(19) United States
(12) Patent Application Publication
(10) Pub. No.: US 2026/0140168 A1
(43) Pub. Date: May 21, 2026

(54) CURRENT CONTROLLED OSCILLATOR (CCO) BASED PARASITIC INDEPENDENT PROCESS MONITORING BLOCK

(71) Applicant: STMicroelectronics International N.V., Geneva (CH)

(72) Inventors: Kedar Janardan DHORI, Ghaziabad (IN); Promod KUMAR, Greater Noida, UP (IN); Sylvain CLERC, Grenoble (FR); Nitin JAIN, Greater Noida, UP (IN); Anand Kumar MISHRA, Ghaziabad, UP (IN)

(73) Assignee: STMicroelectronics International N.V., Geneva (CH)

(21) Appl. No.: 19/389,792

(22) Filed: Nov. 14, 2025

Related U.S. Application Data
(60) Provisional application No. 63/723,198, filed on Nov. 21, 2024.

(51) Int. Cl. G01R 31/28; G01R 31/26; H03K 3/03; H10B 10/00

(52) U.S. Cl. CPC G01R 31/2884; G01R 31/2621; H03K 3/0315; H10B 10/12

(57) ABSTRACT

A process monitoring technique for transistor-based devices is described. The technique utilizes an oscillator-based sensor and operates in two phases: calibration and measurement. During calibration, the oscillator is supplied with a calibration current, and the resulting frequency is measured. A correction factor is calculated by dividing the measured frequency by the calibration current. In the measurement phase, the oscillator is supplied with current from the device under test, such as a memory cell or other transistor-based structure. The frequency produced is measured and divided by the correction factor to determine the current from the device. This approach yields a current value independent of parasitic resistances and capacitances in the oscillator. The technique enables accurate process variation monitoring with little modification to existing circuit structures and is applicable to various transistor-based devices, including SRAM cells, logic circuits, and analog circuits.

### RELATED APPLICATION

This application claims priority to United States Application for Patent No. 63/723,198, filed on Nov. 21, 2024, the content of which is incorporated by reference in its entirety.

### TECHNICAL FIELD

This disclosure relates to the field of semiconductor device manufacturing and testing. More specifically, it pertains to methods and systems for monitoring process variations in transistor-based devices, particularly in static random access memory (SRAM) cells, in a way that is independent of the effects of parasitics.

### BACKGROUND

In the field of semiconductor manufacturing, process variations can impact the performance, power consumption, and reliability of integrated circuits. As semiconductor technologies advance and feature sizes continue to shrink, managing these variations becomes increasingly important. Traditionally, scribe monitors have been used to provide centering information for semiconductor wafers. However, these monitors are limited to a few locations on the wafer (e.g., scribe lines between individual dies in the wafers) and cannot provide detailed information about individual dies.

This limitation has led to the development of process monitor block (PMB) circuits that can be integrated directly into the die, offering more granular process information, enabling manufacturers to optimize chip performance and yield.

PMBs are particularly valuable in System-on-Chip (SoC) designs, where multiple monitors can be integrated to provide within-die information. This fine-grained process data is used for implementing effective process compensation techniques, such as body-bias (BB) adjustment or adaptive voltage scaling. These compensation methods can significantly improve the power, performance, and area characteristics of the integrated circuit.

One common approach to implementing PMBs is through the use of ring oscillators. A sample ring oscillator 5 implemented as a monitor is shown in FIG. 1. The ring oscillator 5 includes a NAND gate having a first input receiving an enable signal ENABLE, a second input receiving the output FOUT of the ring oscillator, and an output connected to an input of an inverter 7. The inverter 7 has its output connected to the input of inverter 8, which in turn has its output connected to the input of inverter 9. The inverter 9 has its output connected to the input of inverter 10, the output of which serves as the output FOUT of the ring oscillator. Note the resistor Rpar connected between the output of the inverter 7 and the input of the inverter 8, representing parasitic resistances in the ring oscillator 5, and the capacitor Cpar connected between the input of the inverter 8 and ground, representing parasitic capacitances in the ring oscillator 5. Note here that for simplicity, the parasitics Rpar and Cpar are only shown on the output of inverter 7, but in reality will be present at the outputs of NAND gate 6, inverter 8, inverter 9, and inverter 10. These parasitics represent a significant drawback: the oscillation frequency is influenced by the parasitic resistances Rpar and capacitances Cpar in addition to the intrinsic characteristics of the components forming the ring oscillator 5.

The dependency on parasitics can lead to inaccurate assessments of the actual device performance, as the measured variations may be more reflective of interconnect variations rather than transistor characteristics. This issue is particularly problematic when trying to monitor specific devices, such as those used in Static Random Access Memory (SRAM) cells, where the individual transistor performance directly impacts critical parameters like Static Noise Margin (SNM) and Write Margin (WM).

Previous attempts to address this issue have included techniques such as the subtraction of measurements from oscillators with and without significant capacitive loads, the use of stacked transistor configurations to improve sensitivity to transistor characteristics, and the modification of SRAM array layouts to incorporate ring oscillator structures.

However, these solutions have their own limitations. Subtraction techniques can introduce additional measurement errors, stacking may not fully eliminate parasitic effects and modifying SRAM layouts can be challenging and may impact the very characteristics being measured.

Furthermore, existing PMB designs often provide composite information that is dependent on both device characteristics and extraction corner effects. This combined data is insufficient for accurately assessing the performance of individual transistors.

There is a clear need for an improved PMB design that can accurately measure individual transistor or device characteristics without being significantly influenced by parasitic effects, provide precise centering information for both NMOS and PMOS devices, minimize or eliminate the need for modifications to existing circuit layouts, offer a simple calibration method to ensure accuracy across different process corners and operating conditions, and enable more effective process compensation techniques to optimize chip performance and yield. Addressing these challenges would represent a significant advancement in the field of process monitoring and control for advanced semiconductor manufacturing processes. As such, further development is needed.

### SUMMARY

According to one or more embodiments as described herein, such a result can be achieved via the features set forth in the claims that follow. Embodiments as described herein can also relate to a corresponding system/method.

The claims are an integral part of the technical teaching provided herein in respect of the embodiments. For example, disclosed herein is a device for monitoring process variations in a semiconductor circuit includes an oscillator that receives an input current and generates an output signal having a frequency based on the input current. A measurement circuit measures the frequency of the output signal. A current generation circuit supplies a calibration current as the input current to the oscillator in a calibration phase. A calibration circuit determines a correction factor based on the measured frequency of the output signal when the calibration current is supplied during the calibration phase. The measurement circuit applies the correction factor to the measured frequency of the output signal when the input current is received from a transistor structure during a normal operation phase to determine the input current. The transistor structure may be a static random access memory (SRAM) cell with a pair of cross coupled inverters, each inverter having a p-channel transistor and an n-channel transistor, a first pass gate transistor connected between a first input/output (IO) node of the cross coupled inverters and a bit line, and a second pass gate transistor connected between a second IO node of the cross coupled inverters and a complementary bit line. The oscillator may connect to either the bit line, complementary bit line, first IO node, or second IO node to receive the input current during normal operation. The device may include a calibration current generator or a frequency to current converter to generate the calibration current. The oscillator may include multiple inverter stages connected in a ring configuration, where each inverter stage has a first transistor and second transistor coupled in series between a supply voltage and ground, a capacitor connected to an output of the inverter stage, and a Schmitt trigger having an input connected to the output of the inverter stage, with an output of a last inverter stage connected to an input of a first inverter stage. Each inverter stage may additionally have a third transistor connected between the supply voltage and the first transistor, and a fourth transistor connected between the second transistor and ground, where the third and fourth transistors control a biasing current for the inverter stage.

A method for monitoring process variations in a semiconductor circuit includes supplying a calibration current to an oscillator during a calibration phase, measuring a first frequency of an output signal generated by the oscillator in response to receiving the calibration current, and determining a correction factor based on the first frequency and the calibration current. The method includes supplying a current to be measured from a transistor structure to the oscillator during a normal operation phase, measuring a second frequency of the output signal generated by the oscillator in response to receiving the current to be measured, and determining the current to be measured by applying the correction factor to the second frequency. The correction factor may be determined by dividing the first frequency by the calibration current. The current to be measured may be determined by dividing the second frequency by the correction factor. The method may include selecting between the calibration current and the current to be measured for supply to the oscillator based on whether a calibration phase or normal operation phase is being performed. The calibration current may be generated using a frequency to current converter based on a clock signal.

A device for monitoring process variations in a semiconductor circuit includes an oscillator that receives an input current and generates an output signal having a frequency based on the input current. A measurement circuit measures the frequency of the output signal. A transistor structure supplies a first current as the input current to the oscillator when the transistor structure is in a first state during a first measurement phase, and supplies a second current as the input current to the oscillator when the transistor structure is in a second state during a second measurement phase. The measurement circuit determines a ratio of the first current to the second current based on the measured frequencies of the output signal during the first measurement phase and second measurement phase. The transistor structure may be a static random access memory (SRAM) cell with a pair of cross coupled inverters, each inverter having a p-channel transistor and an n-channel transistor, a first pass gate transistor connected between a first input/output (IO) node of the cross coupled inverters and a bit line, and a second pass gate transistor connected between a second IO node of the cross coupled inverters and a complementary bit line. The oscillator may connect to the bit line, complementary bit line, first IO node, or second IO node, where the first state corresponds to the SRAM cell storing a logic 0 and the first current is supplied from the connection point, and the second state corresponds to the SRAM cell storing a logic 1 and the second current is supplied to the connection point. The oscillator may include multiple inverter stages connected in a ring configuration, where each inverter stage has a first transistor and second transistor coupled in series between a supply voltage and ground, a capacitor connected to an output of the inverter stage, and a Schmitt trigger having an input connected to the output of the inverter stage, with an output of a last inverter stage connected to an input of a first inverter stage. Each inverter stage may additionally have a third transistor connected between the supply voltage and the first transistor, and a fourth transistor connected between the second transistor and ground, where the third and fourth transistors control a current flow through the inverter stage.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a block diagram of a known process monitoring block used within an integrated circuit.

FIG. 2 is a flowchart illustrating the calibration and measurement phases of a process monitoring technique disclosed herein

FIG. 3 is a schematic diagram of an SRAM cell connected to a current-controlled oscillator-based process monitoring block disclosed herein

FIG. 4 is a schematic diagram of an alternative layout for connecting the process monitoring block to an SRAM cell, as disclosed herein.

FIG. 5 is a detailed schematic diagram of the current-controlled oscillator sensor circuit of FIGS. 3-4.

FIG. 6 is a schematic diagram of a variation of the sensor design using a frequency-to-current converter for reference current generation.

FIG. 7 is a schematic diagram of a variation of the sensor design that lacks generation of a reference current and instead determines the relative strength of n-channel and p-channel transistors of the device under test.

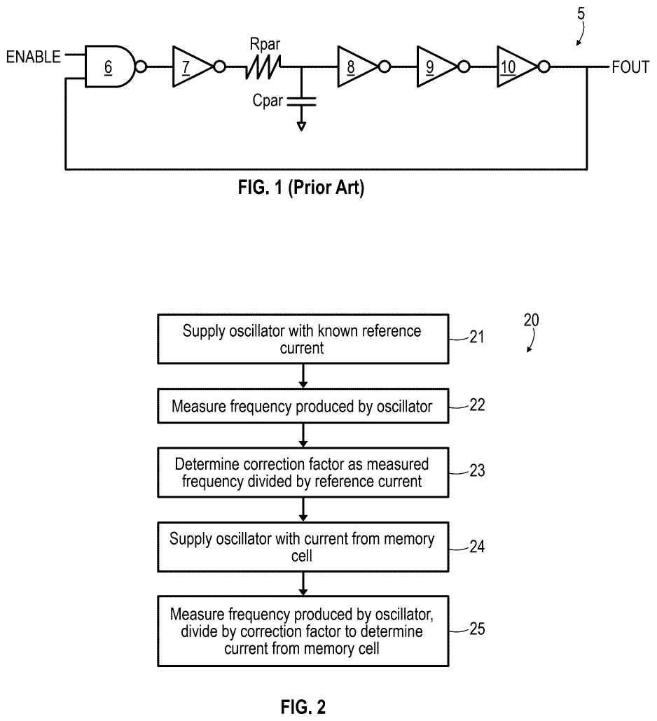

In order to favor the clarity of the features shown, the figures may be drawn in simplified fashion, are not necessarily drawn to scale, and the edges of the figures may not necessarily indicate termination of the extent of the feature.

### DETAILED DESCRIPTION

In the figures and in the rest of the description, like features have been designated by like references in the various figures; as such, a corresponding description may not be repeated for the sake of brevity. In particular, the structural and/or functional features that are common amongst the various embodiments may have the same references and may have identical structural, dimensional, and material properties. Finally, the different embodiments and variants are not exclusive to one another and can be combined amongst themselves.

The references used herein are provided merely for convenience and hence do not define the extent of protection or the scope of the embodiments.

In the ensuing description, one or more specific details are illustrated, aimed at providing an in-depth understanding of embodiments of this invention. The embodiments may be implemented without one or more of the specific details, or with other methods, components, materials, etc. In some cases, known structures, materials, or operations may not be illustrated or described in detail so as to not lose focus on the main aspects of embodiments of the invention.

Reference to “an embodiment” or “one embodiment” in the present description should be understood as meaning “at least one embodiment”. Moreover, phrases such as “in an embodiment” or “in one embodiment” that may be present in one or more points of the present description do not necessarily refer to one and the same embodiment. Moreover, particular configurations, structures, or characteristics may be combined in any manner known to skilled persons in one or more other embodiments.

Unless indicated otherwise, when reference is made to two elements directly connected together, this signifies direct contact of one element to the other without any intermediate elements. When reference is made to two elements connected or coupled together, this signifies that these two elements can be either directly connected or they can be indirectly connected via one or more other intermediate elements.

Unless specified otherwise, the expressions “about”, “around”, “approximately”, “substantially” and “in the order of” signify within 10% or 10°, and preferably within 5% or 5°. Additionally, the phrase “comprised between . . . and . . . ” or equivalent signifies that the end points are included, unless otherwise indicated.

Where not otherwise defined, all technical and scientific terms used herein have the same meaning commonly used by skilled persons in the field pertaining to the present invention. The views included in the attached figures and described herein are not intended as representations of structural features, i.e., constructional limitations, but should be interpreted as representations of functional features, i.e., functions that can be implemented in different ways.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures, or to a . . . as orientated during use as described in the description, but not limited thereby.

Now described with reference to the flowchart 20 of FIG. 2 is the principle behind the process monitoring block circuits described herein. In a calibration phase, an oscillator is supplied with a known reference current (Block 21), and the frequency of the signal produced by the oscillator is measured (Block 22). A correction factor is then calculated as the measured frequency divided by the known reference current (Block 23). The calibration phase is now complete, and a measurement phase begins with supplying the oscillator with current from a memory cell or other transistor-based structure to be measured (Block 24). The frequency produced by the oscillator is then measured and divided by the correction factor to thereby determine the current supplied to the oscillator from the memory cell (Block 25). This resulting current value is independent of parasitic resistances and capacitances in the oscillator, and therefore can be used to accurately perform compensation for process variations.

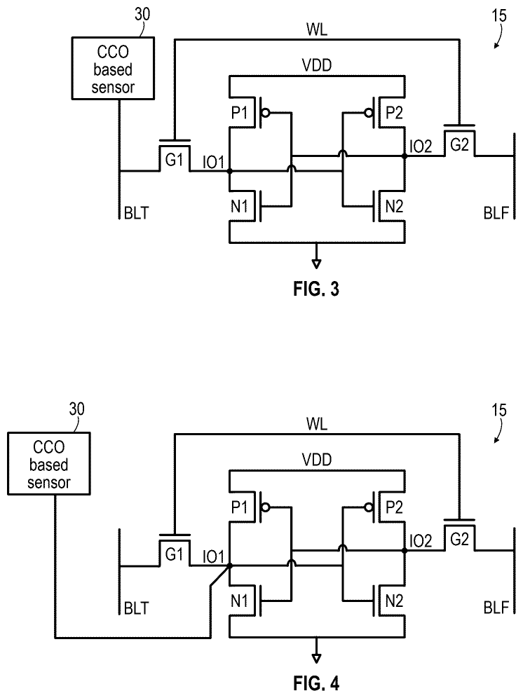

Shown in FIG. 3 is a sample SRAM cell 15 connected to a current controlled oscillator (CCO) based process monitoring block sensor circuit 30. The SRAM cell 15 includes a pair of cross coupled inverters formed by p-channel transistor P1, n-channel transistor N1, p-channel transistor P2, and n-channel transistor N2. In particular: p-channel transistor P1 has its source coupled to a supply voltage VDD, its drain connected to input/output (IO) node IO1 (e.g., a true latch node), and its gate connected to IO node 102 (e.g., a complement latch node); n-channel transistor N1 has its drain connected to IO node IO1, its source coupled to ground, and its gate connected to IO node IO2; p-channel transistor P2 has its source coupled to VDD, its drain connected to IO node IO2, and its gate connected to IO node IO1; and n-channel transistor N2 has its drain connected to IO node IO2, its source coupled to ground, and its gate connected to IO node IO1. The SRAM cell 15 further includes a first pass-gate transistor G1 connected between IO node IO1 and the bit line BLT, and a second pass-gate transistor G2 connected between IO node IO2 and the complementary bit line BLF, with the gates of pass-gate transistors G1 and G2 being coupled to the word line signal WL. Of note is that the monitoring block 30 is connected to the bit line BLT (alternatively, to the complementary bit line BLF).

This offers advantages for SRAM device monitoring, particularly for the centering of the n-channel transistors in SRAM cells. The sensor 30 provides a straightforward sensing mechanism without requiring modifications to the memory array structure, maintaining the existing SRAM design while enabling accurate process monitoring.

An alternative configuration for the connection between the PMB 30 is shown in FIG. 4. Here, the sensor 30 is connected to the IO node IO1 (or IO node 102) as opposed to the bit line BLT. The sensor 30 continues to provide ease of sensing, with only a minimal modification to the array structure. This change allows for direct measurement of the on-currents ION of the transistors of the SRAM cells, which can be used for both n-channel and p-channel centering, depending on the state of the bit cell. The modification to the memory array is minimal, requiring only a via change to connect the sensor to the IO node.

This approach maintains the benefits of the previous configuration while offering additional flexibility. The direct connection to the IO node IO1 (or IO node 102) allows for precise measurements of individual transistor characteristics within the SRAM cell. By toggling the cell state, the sensor 30 can measure ION for both n-channel and p-channel transistors and supply states as required.

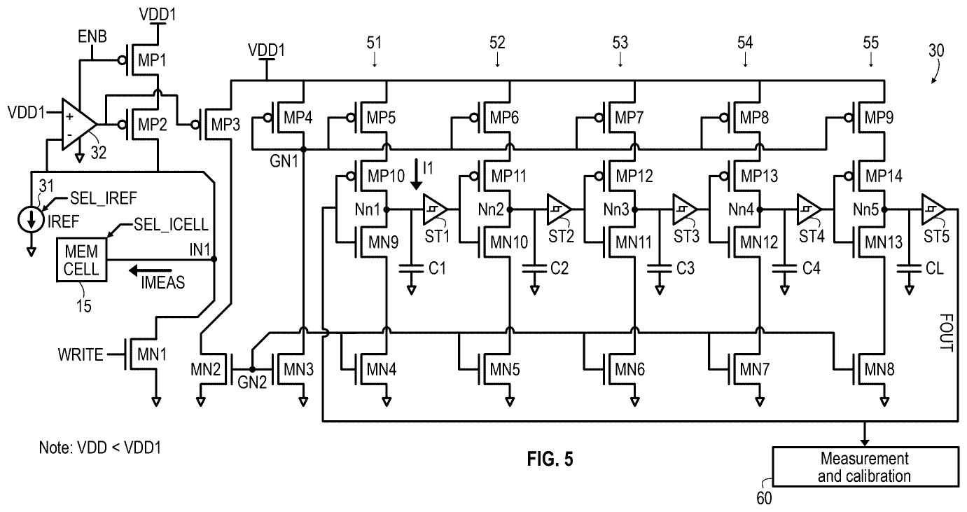

Now described with reference to FIG. 5 is an embodiment of the sensor 30 itself. The sensor 30 includes an input node IN1 (BLT or BLF in FIG. 3, or alternatively IO1 or IO2 in FIG. 4) connected to the memory cell 15 to be tested. Also connected to the input node IN1 is the drain of an n-channel transistor MN1 having its source coupled to ground and its gate coupled to a write signal. A reference current IREF generator 31 is connected between the input node IN1 and ground. A p-channel transistor MP1 has its source coupled to supply node VDD, its drain connected to the source of p-channel transistor MP2, and its gate coupled to receive the enable signal ENB, while the p-channel transistor MP2 has its drain connected to the input node IN1 and its gate connected to the output of error amplifier 32. The error amplifier 32 has its inverting input connected to the input node IN1, its non-inverting input coupled to supply node VDD, and is powered between the supply VDD1 and ground.

A p-channel transistor MP3 has its source coupled to supply node VDD1, its drain connected to the drain of n-channel transistor MN2, and its gate connected to the output of the amplifier 32, while the n-channel transistor MN2 has its source coupled to ground and its gate connected to gate node GN2.

A p-channel transistor MP4 has its source coupled to VDD1, its drain connected to gate node GN1, and its gate connected to gate node GN1. An n-channel transistor MN3 has its drain connected to gate node GN1, its source coupled to ground, and its gate connected to gate node GN2.

Stage 51 of a ring oscillator circuit comprises: a p-channel transistor MP5 having its source coupled to VDD1, its drain connected to the source of p-channel transistor MP10, and its gate connected to gate node GN1, while a p-channel transistor MP10 has its drain connected to node Nn1 and its gate connected to the output of Schmitt trigger ST5. An n-channel transistor MN9 has its drain connected to node Nn1, its source connected to the drain of n-channel transistor MN4, and its gate connected to the output of Schmitt trigger ST5, while the n-channel transistor MN4 has its source coupled to ground and its gate connected to gate node GN2. Here, an inverter is formed by p-channel transistor MP10 and n-channel transistor MN9, while p-channel transistor MP5 and n-channel transistor MN4 provide controllable biasing currents for the inverter, enabling “starving” or control of the slopes of the transitions of the inverter.

A capacitor C1 is connected between node Nn1 and ground, and a Schmitt trigger ST1 has its input connected to node Nn1.

Stage 52 of the ring oscillator circuit comprises: a p-channel transistor MP6 that has its source coupled to VDD1, its drain connected to the source of p-channel transistor MP11, and its gate connected to gate node GN1, while p-channel transistor MP11 has its drain connected to node Nn2 and its gate connected to the output of Schmitt trigger ST1. An n-channel transistor MN10 has its drain connected to node Nn2, its source connected to the drain of n-channel transistor MN5, and its gate connected to the output of Schmitt trigger ST1, while n-channel transistor MN5 has its source coupled to ground and its gate connected to gate node GN2. Here, an inverter is formed by p-channel transistor MP11 and n-channel transistor MN10, while p-channel transistor MP6 and n-channel transistor MN5 provide controllable biasing currents for the inverter, enabling “starving” or control of the slopes of the transitions of the inverter.

A capacitor C2 is connected between node Nn2 and ground, and a Schmitt trigger ST2 has its input connected to node Nn2.

Stage 53 of the ring oscillator circuit comprises: A p-channel transistor MP7 has its source coupled to VDD1, its drain connected to the source of p-channel transistor MP12, and its gate connected to gate node GN1, while p-channel transistor MP12 has its drain connected to node Nn3 and its gate connected to the output of Schmitt trigger ST2. An n-channel transistor MN11 has its drain connected to node Nn3, its source connected to the drain of n-channel transistor MN6, and its gate connected to the output of Schmitt trigger ST2, while n-channel transistor MN6 has its source coupled to ground and its gate connected to gate node GN2. Here, an inverter is formed by p-channel transistor MP12 and n-channel transistor MN11, while p-channel transistor MP7 and n-channel transistor MN6 provide controllable biasing currents for the inverter, enabling “starving” or control of the slopes of the transitions of the inverter.

A capacitor C3 is connected between node Nn3 and ground, and a Schmitt trigger ST3 has its input connected to node Nn3.

Stage 54 of the ring oscillator circuit comprises: A p-channel transistor MP8 has its source coupled to VDD1, its drain connected to the source of p-channel transistor MP13, and its gate connected to gate node GN1, while p-channel transistor MP13 has its drain connected to node Nn4 and its gate connected to the output of Schmitt trigger ST3. An n-channel transistor MN12 has its drain connected to node Nn4, its source connected to the drain of n-channel transistor MN7, and its gate connected to the output of Schmitt trigger ST3, while n-channel transistor MN7 has its source coupled to ground and its gate connected to gate node GN2. Here, an inverter is formed by p-channel transistor MP13 and n-channel transistor MN12, while p-channel transistor MP8 and n-channel transistor MN7 provide controllable biasing currents for the inverter, enabling “starving” or control of the slopes of the transitions of the inverter.

A capacitor C4 is connected between node Nn4 and ground, and a Schmitt trigger ST4 has its input connected to node Nn4.

Stage 55 of the ring oscillator circuit comprises: A p-channel transistor MP9 has its source coupled to VDD1, its drain connected to the source of p-channel transistor MP14, and its gate connected to gate node GN1, while p-channel transistor MP14 has its drain connected to node Nn5 and its gate connected to the output of Schmitt trigger ST4. An n-channel transistor MN13 has its drain connected to node Nn5, its source connected to the drain of n-channel transistor MN8, and its gate connected to the output of Schmitt trigger ST4, while n-channel transistor MN8 has its source coupled to ground and its gate connected to gate node GN2. Here, an inverter is formed by p-channel transistor MP14 and n-channel transistor MN13, while p-channel transistor MP9 and n-channel transistor MN8 provide controllable biasing currents for the inverter, enabling “starving” or control of the slopes of the transitions of the inverter.

A capacitor CL is connected between node Nn5 and ground, and the Schmitt trigger ST5 has its input connected to node Nn4. As stated, the Schmitt trigger ST5 has its output connected to the gates of p-channel transistor MP10 and n-channel transistor MN9. At this output of the Schmitt trigger ST5 is a frequency output signal FOUT, which can be measured by frequency measurement circuitry 60 that then performs the calibrations described herein, or may be converted to a digital count in the case where frequency measurement circuitry 60 comprises a counter, and this digital count may then be used for digital processing and actuation of body-biasing or other modulation measures.

Note that the five stages 51-55 of the ring oscillator shown here are an example, and that other numbers of stages are possible, for example, a greater or fewer number of stages.

The sensor 30, which is essentially a ring oscillator as stated, operates on the principle of current-controlled delay. Each stage 51-55 of the ring oscillator contributes a delay that contains two time components: T1 and T2. Before discussing these components, however, the stages 51-55 will be defined. Stage 51 includes the inverter formed by transistors MP10, MN9 biased by current from transistors MP5, MN4. Stage 52 includes the inverter formed by transistors MP11, MN10 biased by current from transistors MP6, MN5. Stage 53 includes the inverter formed by transistors MP12, MN11 biased by current from transistors MP7, MN6. Stage 54 includes the inverter formed by transistors MP13, MN12 biased by current from transistors MP8, MN7. Stage 55 includes the inverter formed by transistors MP14, MN13 biased by current from transistors MP9, MN8.

Returning to the time components T1 and T2 of each stage 51-55, time T1 is the primary delay component and is dependent on the current I1 flowing through each stage 51-55 and the voltage swing ΔV at the input of the Schmitt trigger ST1-ST4 of that stage. For simplicity, assume the voltage swing ΔV is consistent across all stages 51-55, and is dependent on the magnitude of current I1 as well as the capacitances of C1-C5.

The relationship between time T1, the load capacitance CL, the voltage swing ΔV, and the current I1 can be mathematically represented as:

$$T 1 = ( CL * Δ V ) / I 1.$$

Time T2 represents the delay introduced by each Schmitt trigger ST1-ST4. This component is designed to be significantly smaller than time T1 (T2<<T1) and serves to reduce the slope dependency for the subsequent stage. As non-limiting example values T2 may be less than 1 of T1 (e.g., T2<(0.01*T1))

The frequency of the output signal FOUT is determined by the total delay of all five stages 51-55 in the ring oscillator, and can be mathematically represented as:

$$FOUT = 1 / ( 5 * 2 T ) , where T = T 1 + T 2 .$$

Given that time T2 is negligible compared to time T1, this can be simplified to:

$$FOUT = 1 / ( 5 * 2 T 1 ) = I 1 / ( 5 * 2 * CL * Δ V ) .$$

The current I1 is proportional to the current being measured IMEAS from the memory cell at node IN1. Thus:

$$FOUT = ( IMEAS * X ) / ( 5 * 2 * CL * Δ V ) = IMEAS * A .$$

$$I 1 = IMEAS * X$$

Here, X is a division factor and A is a constant equal to X/(5*2*CL*V). Thus, A is constant but dependent on CL, and thus for each die A is measured for CL.

Note that the inverters of stages 51-55 are starved in the sense that their current is limited by the current source/sink transistors MP5, MN4 (for stage 51), MP6, MN5 (for stage 52), MP7, MN6 (for stage 53), MP8, MN7 (for stage 54), and MP9, MN8 (for stage 55), whose gates are controlled by gate nodes GN1 and GN2. This current starvation allows control over the delay of each stage 51-55, making the oscillator frequency highly dependent on the input current. Stated another way, the voltages at nodes GN1 and GN2 set the operation of transistors MP4 and MN3 as current generators to source/sink a specific current magnitude. The value of FOUT is dependent on that current magnitude, which depends on IMEAS.

To determine the actual current being measured IMEAS, the circuit generates a reference frequency FREF (FOUT=FREF) using a known reference current IREF produced by current source 31 when selected by assertion of SEL_IREF.

$$FREF can be represented as FREF = IREF * A .$$

By taking the ratio of FOUT (produced when the memory cell 15 is selected by assertion of SEL_ICELL) to FREF, the current IMEAS can be calculated as: IMEAS=(FOUT*IREF)/FREF. This measurement technique allows the sensor 30 to accurately determine the current IMEAS drawn by the memory cell 15, independent of variations in temperature or supply voltage that might affect the absolute frequency of the oscillator.

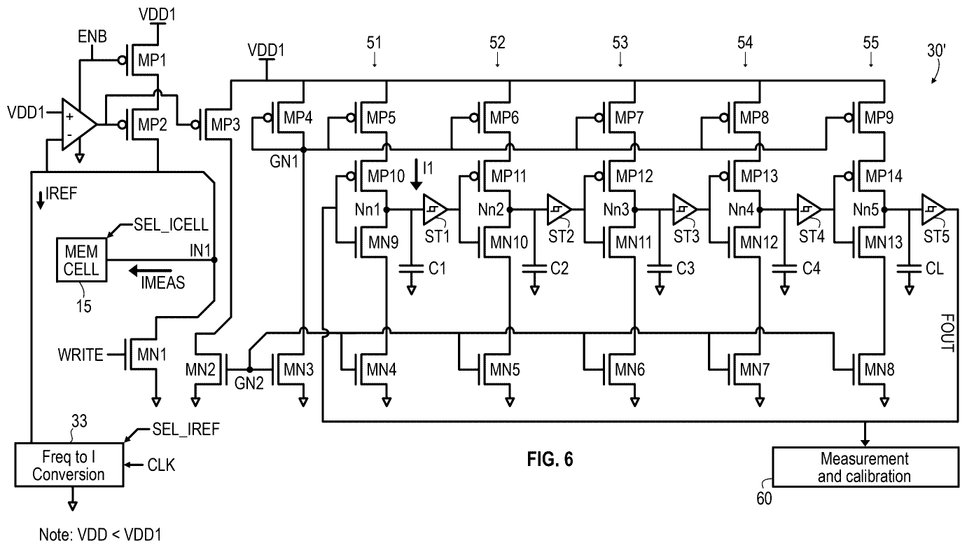

Variations of this design are possible. For example, rather than using a current source 31 to generate the reference current IREF, a frequency to current converter 33 may generate the reference current IREF from the clock signal CLK, as shown in FIG. 6.

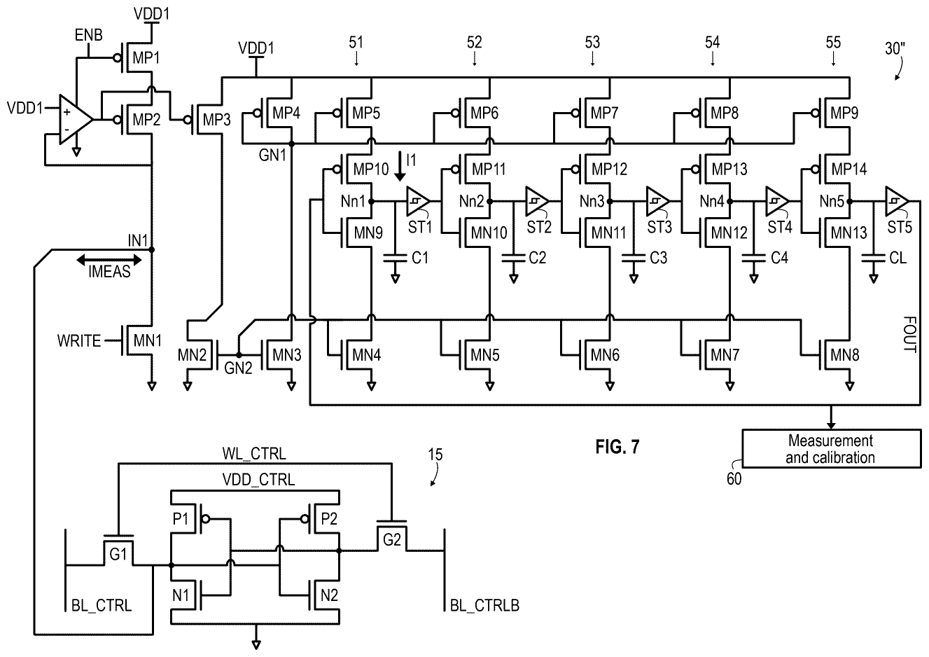

As another embodiment shown in FIG. 7, instead of generating the reference current IREF, the frequency of the output signal FOUT can be measured a first time when IMEAS is sunk from input node IN1 when the memory cell 15 is set to a logic 0, measured a second time when IMEAS is sourced to the input node IN1 when the memory cell 15 is set to a logic 1, and then the ratio of these two measured frequencies of FOUT can be determined. For these measurements, the VDD connection of memory cell 15 is replaced with a controlled supply node VDD_CTRL, while its word line and bit lines are driven by WL_CTRL and BL_CTRL, BT_CTRLB signals respectively. These controlled connections allow precise management of cell states for NMOS and PMOS measurements. These control signals may be generated by the measurement and calibration circuit 60, or by other suitable circuitry.

While the same information is not available using this technique as would be available if a reference current IREF were used, the relative strength between the n-channel transistors and p-channel transistors of the memory cell 15 can be determined. This measurement of relative strength is of interest for assessing and optimizing the balance between n-channel and p-channel transistors in the memory cell 15, because is it a relative measure that can be used for transistor centering via compensation.

The sensors 30 disclosed herein offer several advantages for process monitoring in SRAM devices. The sensors 30, based on a current-controlled oscillator, allow for current measurement without substantial modifications to the memory cell 15 structure. This design enables measurement of both n-channel and p-channel characteristics within the memory cells. The measurement technique reduces the impact of temperature and supply voltage variations on the results. The monitoring method has minimal effect on normal memory operation, allowing for potential in-situ monitoring. Measurement of relative strength between n-channel and p-channel transistors provides information on cell stability and process variations, and the power consumption of this monitoring method is low. Thus, overall, the sensors 30 disclosed herein provide efficient way to perform process monitoring, which can lead to improved memory performance and increased manufacturing yield.

Various embodiments and variants have been described. Those skilled in the art will understand that certain features of these embodiments can be combined and other variants. Indeed, while the above has been described in the context of memory cells, the process monitoring technique is applicable to a wide range of transistor-based devices. The sensor can be connected to any node where current measurement is desired, such as the drain or source of individual transistors, outputs of logic gates, or bit lines of other memory structures. This versatility allows for process variation monitoring in various integrated circuit designs, including but not limited to logic circuits, analog circuits, and other types of memory devices. The ability to measure relative strengths of n-channel and p-channel transistors makes this technique useful for assessing and optimizing CMOS designs across different manufacturing processes. By providing a way to accurately measure transistor characteristics with minimal circuit modification, a practical technique for process variation monitoring in semiconductor device fabrication beyond just memory and SRAM applications is provided.

While this invention has been described with reference to illustrative embodiments, this description is not intended to be construed in a limiting manner. Various modifications and combinations of the illustrative embodiments, as well as other embodiments of the invention, will be apparent to skilled persons in the field of the invention upon reference to the description and the figures. It is therefore intended that the appended claims encompass any such modifications or embodiments.

Finally, the practical implementation of the embodiments and variants described herein is within the capabilities of those skilled in the art based on the functional description provided hereinabove while falling within the scope of the invention as defined in the attached claims.

1. A device for monitoring process variations in a semiconductor circuit, comprising:
an oscillator configured to receive an input current and generate an output signal having a frequency based on the input current;
a measurement circuit configured to measure the frequency of the output signal;
a current generation circuit configured to supply a calibration current as the input current to the oscillator in a calibration phase;
a calibration circuit configured to determine a correction factor based on the measured frequency of the output signal when the calibration current is supplied during the calibration phase; and
wherein the measurement circuit is configured to apply the correction factor to the measured frequency of the output signal when the input current is received from a transistor structure during a normal operation phase to thereby determine the input current.

2. The device of claim 1,
wherein the transistor structure is a static random-access memory (SRAM) cell comprising: a pair of cross-coupled inverters, each inverter comprising a p-channel transistor and an n-channel transistor; a first pass-gate transistor connected between a first input/output (IO) node of the cross-coupled inverters and a bit line; and a second pass-gate transistor connected between a second IO node of the cross-coupled inverters and a complementary bit line; and
wherein the oscillator is connected to the bit line or the complementary bit line to receive the input current during the normal operation phase.

3. The device of claim 1,
wherein the transistor structure is a static random-access memory (SRAM) cell comprising: a pair of cross-coupled inverters, each inverter comprising a p-channel transistor and an n-channel transistor; a first pass-gate transistor connected between a first input/output (IO) node of the cross-coupled inverters and a bit line; and a second pass-gate transistor connected between a second IO node of the cross-coupled inverters and a complementary bit line; and
wherein the oscillator is connected to first IO node or the second IO node to receive the input current during the normal operation phase.

4. The device of claim 1, further comprising a calibration current generator configured to generate the calibration current.

5. The device of claim 1, further comprising a frequency-to-current converter configured to generate the calibration current from a clock signal.

6. The device of claim 1, wherein the oscillator comprises:
a plurality of inverter stages connected in a ring configuration, each inverter stage comprising:
a first transistor and a second transistor coupled in series between a supply voltage and ground;
a capacitor connected to an output of the inverter stage; and
a Schmitt trigger having an input connected to the output of the inverter stage;
wherein an output of a last inverter stage in the ring configuration is connected to an input of a first inverter stage in the ring configuration.

7. The device of claim 6, wherein each inverter stage further comprises:
a third transistor connected between the supply voltage and the first transistor; and
a fourth transistor connected between the second transistor and ground;
wherein the third transistor and fourth transistor control a biasing current for the inverter stage.

8. A method for monitoring process variations in a semiconductor circuit, the method comprising:
supplying a calibration current to an oscillator during a calibration phase;
measuring a first frequency of an output signal generated by the oscillator in response to receiving the calibration current;
determining a correction factor based on the first frequency and the calibration current;
supplying a current to be measured from a transistor structure to the oscillator during a normal operation phase;
measuring a second frequency of the output signal generated by the oscillator in response to receiving the current to be measured; and
determining the current to be measured by applying the correction factor to the second frequency.

9. The method of claim 8, wherein determining the correction factor comprises dividing the first frequency by the calibration current.

10. The method of claim 8, wherein determining the current to be measured comprises dividing the second frequency by the correction factor.

11. The method of claim 8, further comprising:
selecting between the calibration current and the current to be measured for supply to the oscillator based on whether a calibration phase or a normal operation phase is being performed.

12. The method of claim 8, wherein the calibration current is generated using a frequency-to-current converter based on a clock signal.

13. A device for monitoring process variations in a semiconductor circuit, comprising:
an oscillator configured to receive an input current and generate an output signal having a frequency based on the input current;
a measurement circuit configured to measure the frequency of the output signal;
a transistor structure configured to supply a first current as the input current to the oscillator when the transistor structure is in a first state during a first measurement phase, and to supply a second current as the input current to the oscillator when the transistor structure is in a second state during a second measurement phase; and
wherein the measurement circuit is configured to determine a ratio of the first current to the second current based on the measured frequencies of the output signal during the first measurement phase and the second measurement phase.

14. The device of claim 13,
wherein the transistor structure is a static random-access memory (SRAM) cell comprising: a pair of cross-coupled inverters, each inverter comprising a p-channel transistor and an n-channel transistor; a first pass-gate transistor connected between a first input/output (IO) node of the cross-coupled inverters and a bit line; and a second pass-gate transistor connected between a second IO node of the cross-coupled inverters and a complementary bit line;
wherein the oscillator is connected to the bit line or the complementary bit line to receive the input current during the normal operation phase; and
wherein the first state corresponds to the SRAM cell storing a logic 0 and the first current is supplied from the bit line or complementary bit line, and and the second state corresponds to the SRAM cell storing a logic 1 and the second current is supplied to the bit line or complementary bit line.

15. The device of claim 13,
wherein the transistor structure is a static random-access memory (SRAM) cell comprising: a pair of cross-coupled inverters, each inverter comprising a p-channel transistor and an n-channel transistor; a first pass-gate transistor connected between a first input/output (IO) node of the cross-coupled inverters and a bit line; and a second pass-gate transistor connected between a second IO node of the cross-coupled inverters and a complementary bit line;
wherein the oscillator is connected to the first IO node or the second IO node to receive the input current during the normal operation phase; and
wherein the first state corresponds to the SRAM cell storing a logic 0 and the first current is supplied from the first IO node or the second IO node, and the second state corresponds to the SRAM cell storing a logic 1 and the second current is supplied to the first IO node or the second IO node.

16. The device of claim 13, wherein the oscillator comprises:
a plurality of inverter stages connected in a ring configuration, each inverter stage comprising:
a first transistor and a second transistor coupled in series between a supply voltage and ground;
a capacitor connected to an output of the inverter stage; and
a Schmitt trigger having an input connected to the output of the inverter stage;
wherein an output of a last inverter stage in the ring configuration is connected to an input of a first inverter stage in the ring configuration.

17. The device of claim 16, wherein each inverter stage further comprises:
a third transistor connected between the supply voltage and the first transistor; and
a fourth transistor connected between the second transistor and ground;
wherein the third transistor and fourth transistor control a current flow through the inverter stage.
